(19) United States
(12) Patent Application Publication
(10) Pub. No.: US 2025/0374784 A1
(43) Pub. Date: Dec. 4, 2025

(54) DISPLAY PANEL, ELECTRONIC DEVICE, AND MANUFACTURING METHOD OF THE DISPLAY PANEL

(71) Applicant: Samsung Display Co., Ltd., Yongin-si, Gyeonggi-do (KR)

(72) Inventors: HANBUM KWON, Yongin-si (KR); EUNBYUL KIM, Yongin-si (KR); YOUNGMIN AHN, Yongin-si (KR)

(21) Appl. No.: 19/209,689

(22) Filed: May 15, 2025

(30) Foreign Application Priority Data
May 30, 2024 (KR) 10-2024-0070986

(51) Int. Cl. H10K 59/131; H10K 59/12

(52) U.S. Cl. CPC H10K 59/131; H10K 59/1201

(57) ABSTRACT

A display panel includes a pixel, a signal line electrically connected to the pixel, and a signal pad connected to the signal line. The signal pad includes a first conductive pattern connected to one side portion of the signal line, a second conductive pattern disposed on the first conductive pattern, and an insulating pattern including a first portion disposed on the first conductive pattern and a second portion disposed on the first portion, the first portion has a pillar shape, and the second portion has a dome shape.

### CROSS-REFERENCE TO RELATED APPLICATION

The present application claims priority to and the benefit of Korean Patent Application No. 10-2024-0070986, filed on May 30, 2024, in the Korean Intellectual Property Office, the entire content of which is incorporated here by reference.

### BACKGROUND

### 1. Field

The present disclosure herein relates to a display panel, an electronic device including the display panel, and a manufacturing method of the display panel, and for example, a display panel including a pad region, an electronic device including the display panel, and a manufacturing method of the display panel.

### 2. Description of the Related Art

A display device includes a display region that activates in response to an electrical signal. Through this display region, the display device may sense external inputs (e.g., inputs applied from the outside) and concurrently (e.g., simultaneously) display one or more suitable images to provide information to a user.

The display device includes a display panel and a circuit board. The display panel may be connected to a main board through the circuit board. Additionally, a driving chip may be mounted on the display panel.

### SUMMARY

Aspects according to one or more embodiments of the present disclosure are directed toward a display panel with (e.g., having) enhanced (e.g., improved) bonding reliability, and an electronic device including the display panel.

An aspect according to one or more embodiments of the present disclosure is directed toward a manufacturing method of a display panel having improved processability. Additional aspects will be set forth in part in the description which follows and, in part, will be apparent from the description, or may be learned by practice of the presented embodiments of the disclosure.

According to one or more embodiments, a display panel includes a pixel, a signal line electrically connected to the pixel, and a signal pad connected to the signal line, wherein the signal pad includes a first conductive pattern connected to one side portion of the signal line, a second conductive pattern arranged on the first conductive pattern, and an insulating pattern including a first portion arranged on the first conductive pattern and a second portion arranged on the first portion, the first portion has a pillar shape, and the second portion has a dome shape.

In one or more embodiments, in a plan view, the insulating pattern may be arranged on an inner side of each of the first conductive pattern and the second conductive pattern.

In one or more embodiments, the insulating pattern may be directly arranged on the first conductive pattern, and the second conductive pattern may cover (e.g., may be on) the insulating pattern and a portion of the first conductive pattern on which the insulating pattern is not arranged.

In one or more embodiments, the first portion may include an upper surface in contact with the second portion, the second portion may include a lower surface in contact with the first portion, and the upper surface of the first portion and the lower surface of the second portion may be identical surfaces that match each other. For example, the upper surface of the first portion may be congruent to the lower surface of the second portion. For example, the first portion may have an upper surface in contact with the second portion, while the second portion may have a lower surface in contact with the first portion. These surfaces may be identical, meaning the upper surface of the first portion is congruent to the lower surface of the second portion. In one or more embodiments, the first portion may have a quadrangular shape in a cross-sectional view, the second portion may include an upper surface in contact with the second conductive pattern, and the upper surface of the second portion may have an upwardly convex shape.

In one or more embodiments, an elastic modulus of the first portion may be greater than an elastic modulus of the second portion.

In one or more embodiments, the first portion may be formed from a negative photoresist material, and the second portion may be formed from a positive photoresist material. For example, the first portion may include a material formed from a negative photoresist material, and the second portion may include a material formed from a positive photoresist material.

In one or more embodiments, the first portion may have a multi-layered structure.

In one or more embodiments, the first portion and the second portion may each independently include a polymer.

In one or more embodiments of the disclosure, an electronic device includes a display module; a window arranged on the display module; and an accommodation member accommodating the display module, wherein the display module includes a pixel, a signal line electrically connected to the pixel, and a signal pad connected to the signal line, wherein the signal pad includes a first conductive pattern connected to one side portion of the signal line, a second conductive pattern arranged on the first conductive pattern, and an insulating pattern including a first portion arranged on the first conductive pattern and a second portion arranged on the first portion, and an elastic modulus of the first portion is greater than an elastic modulus of the second portion.

In one or more embodiments, in a plan view, the insulating pattern may be arranged on an inner side of each of the first conductive pattern and the second conductive pattern.

In one or more embodiments, the insulating pattern may be directly arranged on the first conductive pattern, and the second conductive pattern may cover (e.g., may be on) the insulating pattern and a portion of the first conductive pattern on which the insulating pattern is not arranged.

In one or more embodiments, the first portion may include an upper surface in contact with the second portion, the second portion may include a lower surface in contact with the first portion, and the upper surface of the first portion and the lower surface of the second portion may be substantially identical surfaces that match each other. For example, the upper surface of the first portion may be congruent to the lower surface of the second portion.

In one or more embodiments, the first portion may have a pillar shape, and the second portion may have a dome shape.

In one or more embodiments, the first portion may have a quadrangular shape in a cross-sectional view, the second portion may include an upper surface being in contact with the second conductive pattern, and the upper surface of the second portion may have an upwardly convex shape.

In one or more embodiments, the first portion may be formed from a negative photoresist material, and the second portion may be formed from a positive photoresist material. For example, the first portion may include a material formed from a negative photoresist material, and the second portion may include a material formed from a positive photoresist material.

In one or more embodiments, the first portion may have a multi-layered structure.

In one or more embodiments, the first portion and the second portion may each independently include a polymer.

In one or more embodiments of the present disclosure, a manufacturing method of a display panel includes providing a preliminary signal pad including a first conductive pattern connected to one side portion of a signal line, and forming, on the preliminary signal pad, an insulating pattern including a first portion and a second portion, wherein the forming of the insulating pattern includes forming the first portion on the preliminary signal pad in a first region by using a negative photoresist material, and forming the second portion on the first portion by using a positive photoresist material.

In one or more embodiments, the forming of the first portion may include applying the negative photoresist material onto the preliminary signal pad, exposing the negative photoresist material in the first region, and forming the first portion in the first region by developing and curing the negative photoresist material, and the forming of the second portion may include applying the positive photoresist material onto the preliminary signal pad and the first portion, exposing a second region, around (e.g., surrounding) the first region in a plan view, of the positive photoresist material, and forming the second portion on the first portion by developing and curing the positive photoresist material.

In one or more embodiments, the first portion may be in a pillar shape, and the second portion may be in a dome shape.

In one or more embodiments, an elastic modulus of the first portion may be formed to be greater than an elastic modulus of the second portion.

### BRIEF DESCRIPTION OF THE DRAWINGS

The accompanying drawings are included to provide a further understanding of the present disclosure, and are incorporated in and constitute a part of this specification. The drawings illustrate embodiments of the present disclosure and, together with the description, serve to explain principles of the present disclosure. In the drawings:

FIG. 1 is an assembled perspective view of a display device according to one or more embodiments of the present disclosure;

FIGS. 2A and 2B are each an exploded perspective view of a display device according to one or more embodiments of the present disclosure;

FIG. 3 is a cross-sectional view of a display module according to one or

more embodiments of the present disclosure;

FIG. 4 is a plan view of a display panel according to one or more embodiments of the present disclosure;

FIG. 5 is a cross-sectional view of a display panel illustrating a pixel according to one or more embodiments of the present disclosure;

FIG. 6 is an enlarged exploded perspective view of a pad region of a display device according to one or more embodiments of the present disclosure;

FIG. 7A is a schematic plan view of a pad region according to one or more embodiments of the present disclosure;

FIGS. 7B-7D are each a cross-sectional view of a pad region according to one or more embodiments of the present disclosure;

FIG. 8 is a cross-sectional view illustrating a bonding structure of a display device according to one or more embodiments of the present disclosure; and

FIGS. 9A-9H are each a cross-sectional view illustrating a step (e.g., act or task) of a manufacturing method of a pad region according to one or more embodiments of the present disclosure.

### DETAILED DESCRIPTION

In this specification, it will be understood that if (e.g., when) an element (or a region, a layer, a portion, and/or the like) is referred to as being “on”, “connected to” or “coupled to” another element, it may be directly arranged on, connected or coupled to the other element, or an intervening element may be arranged therebetween.

Like reference numerals or symbols refer to like elements. Also, in the drawings, the thicknesses, ratios, and dimensions of the elements are exaggerated for effective description of the technical contents. The term “and/or” includes all of one or more combinations which may be defined by related elements.

Although the terms first, second, and/or the like, may be used herein to describe various elements, these elements should not be limited by these terms. These terms are only used to distinguish one element from another element. For example, a first element may be referred to as a second element, and similarly, a second element may also be referred to as a first element without departing from the scope of the present disclosure. The singular forms include the plural forms as well unless the context clearly indicates otherwise.

In addition, terms such as “below”, “on lower side”, “above”, and “on upper side” may be used herein to describe the relationships of the elements illustrated in the drawings. These terms have relative concepts and are described on the basis of the directions indicated in the drawings.

It will be understood that the terms such as “include” or “have”, if (e.g., when) used herein, are intended to specify the presence of stated features, integers, steps, operations, elements, components, and/or one or more (e.g., any suitable) combinations thereof, but do not preclude the presence or addition of one or more other features, integers, steps, operations, elements, components, and/or one or more (e.g., any suitable) combinations thereof.

Unless otherwise defined, all terms (including technical and scientific terms) used herein have the same meaning as commonly understood by one of ordinary skill in the art to which the present disclosure belongs. Also, terms, such as those defined in commonly used dictionaries, should be interpreted as having a meaning that is consistent with their meaning in the context of the relevant art and should not be interpreted in an idealized or overly formal sense unless expressly so defined herein.

Hereinafter, embodiments of the present disclosure will be described with reference to the drawings.

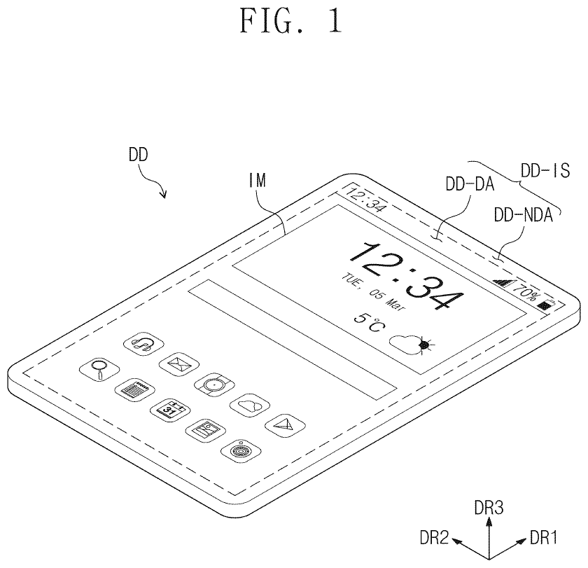

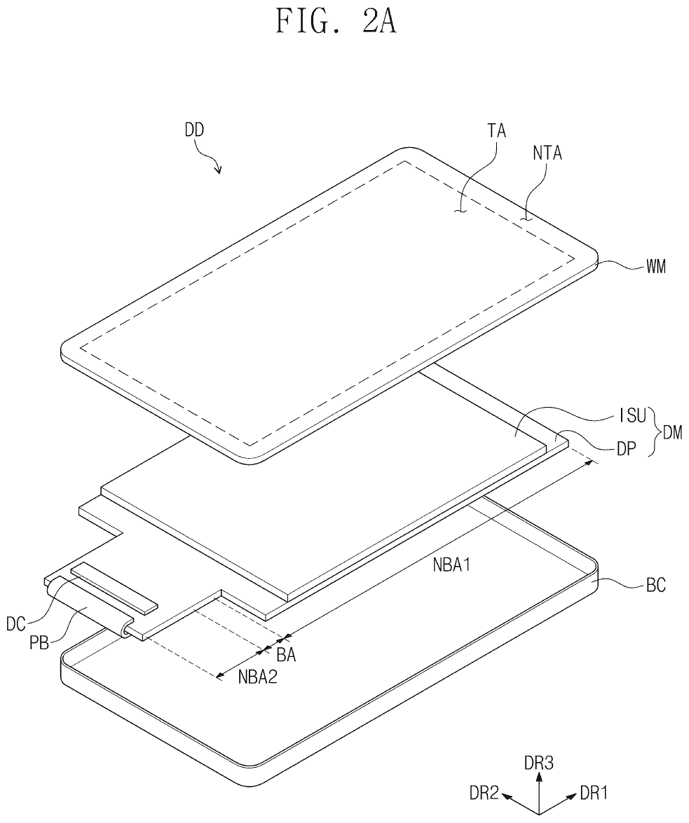

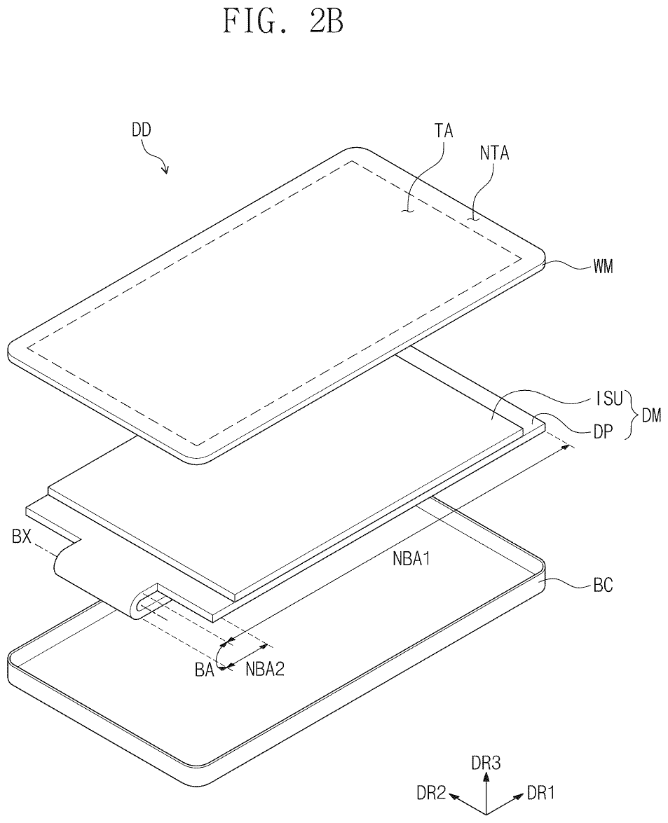

FIG. 1 is a perspective view of a display device DD according to one or more embodiments of the present disclosure. FIGS. 2A and 2B are each an exploded perspective view of a display device DD according to one or more embodiments of the present disclosure. FIG. 2B illustrates, as an example, the display device DD in a state in which a bending region BA illustrated in FIG. 2A is bent.

Referring to FIG. 1, as an example, the display device DD is illustrated as a mobile phone terminal. The display device DD according to the present disclosure may be applied to a small- and/or medium-sized electronic device such as a tablet PC, a car navigation device, a game console, and/or a smart watch as well as a large-sized electronic device such as a television and/or a monitor.

The display device DD may have a rectangular shape having long sides extending in a first direction DR1 and short sides extending in a second direction DR2 crossing the first direction DR1 in a plan view. However, the present disclosure is not limited thereto, and the display device DD may have one or more suitable shapes such as a circular shape or a polygonal shape in a plan view.

Hereinafter, a direction that is substantially normal to (e.g., perpendicularly crosses) a plane defined by the first direction DR1 and the second direction DR2 will be defined as a third direction DR3. As used herein, the phrase “in a plan view” may refer to a state of being viewed in the third direction DR3.

A “cross-sectional view” refers to a view that is taken by cutting through the display device DD along a plane that is normal or perpendicular to the plane defined by the first direction DR1 and the second direction DR2. This refers looking at the internal structure of the display device DD as if it has been sliced along this plane, revealing the arrangement and relationship of internal components in the third direction DR3.

The display device DD may be rigid or flexible. The term “flexible” may refer to bendable characteristics, and the display device DD may be a device including any one from among a structure which is completely foldable to a structure which is bendable to a level of several nanometers. For example, the display device DD may include any suitable structure ranging from completely foldable to bendable at a nanometer scale. Also, for example, the flexible display device DD may include a curved display device, a rollable display device, and a foldable display device.

The display device DD may display an image IM through a display surface DD-IS. Icon images are illustrated as an example of the image IM. The display surface DD-IS may be parallel to a plane defined by the first direction DR1 and the second direction DR2.

The display surface DD-IS may include a display region DD-DA in which the image IM is displayed and a non-display region DD-NDA adjacent to the display region DD-DA. The non-display region DD-NDA may be a region in which an image IM is not displayed. However, the present disclosure is not limited thereto, and the non-display region DD-NDA may be adjacent to any one side of the display region DD-DA or may not be provided.

Referring to FIGS. 2A and 2B, the display device DD may include a window WM, a display module DM, and an accommodation member BC.

The window WM may be arranged on the display module DM and transmit an image provided from the display module DM to the outside. In some embodiments, the window WM may include a base layer and functional layers arranged on the base layer. The functional layers may include a protective layer, an anti-fingerprint layer, and/or the like. The base layer of the window WM may include glass, sapphire, plastic, and/or the like. The base layer of the window WM may include an optically transparent insulating material. For example, the base layer of the window WM may include glass or a plastic film, or a glass substrate and a plastic film bonded by an adhesive agent.

The window WM may include a transmission region TA and a non-transmission region NTA. The transmission region TA may overlap the display region DD-DA illustrated in FIG. 1 and have a shape corresponding to that of the display region DD-DA. The non-transmission region NTA may overlap the non-display region DD-NDA illustrated in FIG. 1 and have a shape corresponding to that of the non-display region DD-NDA. The non-transmission region NTA may be a region of which a light transmittance is relatively low compared to the transmission region TA. The non-transmission region NTA may be defined by a bezel pattern in a partial region of a base layer of the window WM, and a region in which a bezel pattern is not arranged may be defined as the transmission region TA. However, the present disclosure is not limited thereto, and the non-transmission region NTA may not be provided.

In some embodiments, an anti-reflective layer may be arranged between the window WM and the display module DM. The anti-reflective layer may reduce reflectance of external light incident from outside on the display device DD. The anti-reflective layer may include color filters. The color filters may have an arrangement (e.g., may be arranged in a certain configuration or pattern). For example, the color filters may be arranged in consideration of the colors of emitted light from pixels included in a display panel DP (to be described in more detail later). In addition, the anti-reflective layer may further include a black matrix adjacent to the color filters.

According to one or more embodiments of the present disclosure, the display module DM may include the display panel DP and an input sensor ISU.

The display panel DP may be any one selected from among a liquid crystal display panel, an electrophoretic display panel, a microelectromechanical system (MEMS) display panel, an electrowetting display panel, an organic light-emitting display panel, an inorganic light-emitting display panel, and a quantum dot light-emitting display panel. However, the present disclosure may not be particularly limited thereto. Hereinafter, as an example, the display panel DP will be described as an organic light-emitting display panel.

The input sensor ISU may include any one selected from among a capacitive sensor, an optical sensor, an ultrasonic sensor, and an electromagnetic induction sensor. The input sensor ISU may be formed on the display panel DP through a substantially continuous process, or may be separately manufactured and then attached to an upper side of the display panel DP through an adhesive layer, but the present disclosure is not limited to any embodiments.

The display device DD may further include a driving chip DC arranged on the display panel DP. The display device DD may further include a circuit board PB arranged on the display panel DP. In the present embodiment, the circuit board PB may be a flexible circuit board, but the present disclosure is not limited thereto. In some embodiments, the circuit board PB may be rigid. The circuit board PB may electrically connect the display panel DP and a main circuit board.

The driving chip DC may include driving elements, for example, a data driving circuit, for driving a pixel of the display panel DP. FIG. 2A illustrates a structure in which the driving chip DC is mounted on the display panel DP, but the present disclosure is not limited thereto. For example, the driving chip DC may be mounted on the circuit board PB. In the present embodiment, the circuit board PB and the driving chip DC directly mounted on the display panel DP may (e.g., collectively) be referred to as an electronic component.

The display panel DP may include a bending region BA, and a first non-bending region NBA1 and a second non-bending region NBA2 arranged to be spaced and/or apart (e.g., spaced apart or separated) from each other in a first direction DR1 with the bending region BA therebetween.

The bending region BA may be defined as a region in which the display panel DP is bent along a virtual bending axis BX extending in a second direction DR2. The first non-bending region NBA1 may be defined as a region overlapping the transmission region TA, and the second non-bending region NBA2 may be defined as a region to which the circuit board PB is connected or mounted. When the bending region BA is bent with respect to the bending axis BX, the circuit board PB and the driving chip DC may be bent in a direction toward a rear surface of the display panel DP and arranged below the rear surface of the display panel DP. In some embodiments, additional components may be arranged to compensate for a step (e.g., height difference) between the rear surface of the display panel DP and the circuit board PB formed by the bending region BA.

According to one or more embodiments, in the second direction DR2, a width of the first non-bending region NBA1 may be greater than the width of the bending region BA and greater than the width of the second non-bending region NBA2.

However, the present disclosure is not limited thereto, and the bending region BA may have such a shape that a width of the bending region BA in the second direction DR2 decreases from the first non-bending region NBA1 toward the second non-bending region NBA2, and is not limited to any one or more embodiments. For example, the bending region BA may have a shape where the width of the bending region BA in the second direction DR2 is the same as or similar to the width of the first non-bending region NBA1, and gradually decreases toward the second non-bending region NBA2 along the first direction DR1.

As illustrated in FIG. 2B, because a portion of the display panel DP is bent, the circuit board PB electrically bonded to the display panel DP may be arranged on the rear surface of the display panel DP.

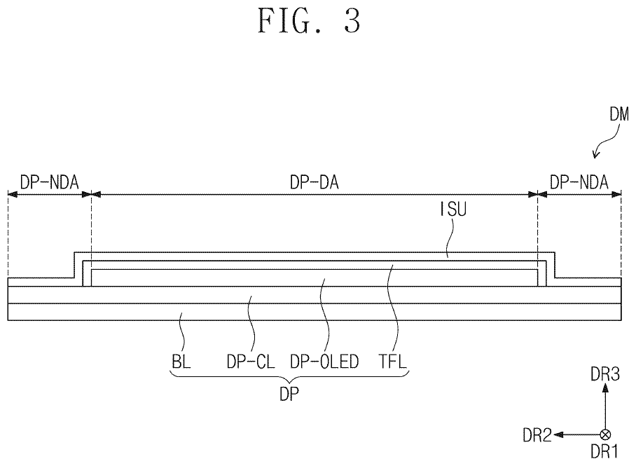

The accommodation member BC may accommodate the display module DM and may be coupled to the window WM. The circuit board PB may be arranged on one end of the display panel DP and electrically connected to a circuit element layer DP-CL to be described in more detail with reference to FIG. 3. In some embodiments, the display device DD may further include a main board, electronic modules mounted on the main board, a camera module, a power module, and/or the like.

While a mobile phone terminal is described above as an example of the display device DD, according to some embodiments, the display device DD may include at least two (two or more) bonded electronic components. In some embodiments, the display panel DP and the driving chip DC mounted on the display panel DP may correspond to (e.g., be considered as) different electronic components, and the display device DD may be configured (e.g., may be constructed with) only with the display panel DP and the driving chip DC mounted on the display panel DP. In some embodiments, the display panel DP and the circuit board PB connected to the display panel DP may also correspond to (e.g., be considered as) different electronic components, and the display device DD may be configured (e.g., may be constructed with) only with the display panel DP and the circuit board PB connected to the display panel DP. Also, in some embodiments, the display device DD may be configured (e.g., may be constructed with) only with a main board and an electronic module mounted on the main board. Hereinafter, the display device DD according to the present disclosure will be described with a focus on a bonding structure of the display panel DP and the driving chip DC mounted on the display panel DP.

FIG. 3 is a cross-sectional view of a display module DM according to one or more embodiments of the present disclosure.

Referring to FIG. 3, a display panel DP may include a base layer BL, a circuit element layer DP-CL, a display element layer DP-OLED, and an upper insulating layer TFL. An input sensor ISU may be arranged on the upper insulating layer TFL.

The display panel DP may include a display region DP-DA and a non-display region DP-NDA. The display region DP-DA of the display panel DP may correspond to the display region DD-DA illustrated in FIG. 1 or the transmission region TA illustrated in FIG. 2A, and the non-display region DP-NDA may correspond to the non-display region DD-NDA illustrated in FIG. 1 or the non-transmission region NTA illustrated in FIG. 2A.

The base layer BL may include at least one plastic film (e.g., polymer film). The base layer BL may be a flexible substrate and include a plastic (e.g., polymer) substrate, a glass substrate, a metal substrate, an organic/inorganic composite material substrate, and/or the like.

The circuit element layer DP-CL may include at least one intermediate insulating layer and a circuit element. The intermediate insulating layer may include at least one intermediate inorganic layer and at least one intermediate organic layer. The circuit element may include signal lines, a pixel driving circuit, and/or the like. An insulating layer, a semiconductor layer, and a conductive layer may be formed through coating, depositing, and/or the like. Thereafter, the insulating layer, the semiconductor layer, and the conductive layer may be selectively patterned through photolithography and etching processes. Through these processes, a semiconductor pattern, a conductive pattern, a signal line, and/or the like, are formed. Patterns arranged on the same layer may be formed through substantially the same process. Hereinafter, the expression “patterns are formed through substantially the same process” refers to that the patterns are formed to include the same material and the same stacked structure.

The display element layer DP-OLED may include a plurality of light-emitting elements. The display element layer DP-OLED may further include an organic layer such as a pixel-defining film.

The upper insulating layer TFL may encapsulate the display element layer DP-OLED. The upper insulating layer TFL may be arranged on the display element layer DP-OLED. The upper insulating layer TFL may overlap the display region DP-DA and the non-display region DP-NDA. The upper insulating layer TFL may overlap at least partial (e.g., a portion of the) non-display region DP-NDA. For example, the upper insulating layer TFL may include a thin-film encapsulation layer. The thin-film encapsulation layer may include a stacked structure of an inorganic layer, an organic layer, and an inorganic layer. The upper insulating layer TFL may protect the display element layer DP-OLED from moisture, oxygen, and/or foreign substances such as dust particles. However, the present disclosure is not limited thereto, and the upper insulating layer TFL may further include an additional insulating layer in addition to the thin-film encapsulation layer. For example, the upper insulating layer TFL may further include an optical insulating layer for controlling refractive index.

In one or more embodiments of the present disclosure, an encapsulation substrate may be provided instead of the upper insulating layer TFL. In this case, the encapsulation substrate may be opposed to the base layer BL (e.g., may be arranged opposite to (e.g., facing) the base layer BL), and the circuit element layer DP-CL and the display element layer DP-OLED may be arranged between the encapsulation substrate and the base layer BL.

The input sensor ISU may be directly arranged on the display panel DP. As used herein, the wording “component A is directly arranged on component B” refers to that a separate layer (e.g., an intermediate layer) is not arranged between component A and component B. In the present embodiment, the input sensor ISU may be manufactured through a substantially continuous process along with the display panel DP. However, the technical spirit of the present disclosure is not limited thereto, and the input sensor ISU may be provided as an individual panel and coupled to the display panel DP through an adhesive layer. In one or more embodiments, the input sensor ISU may not be provided.

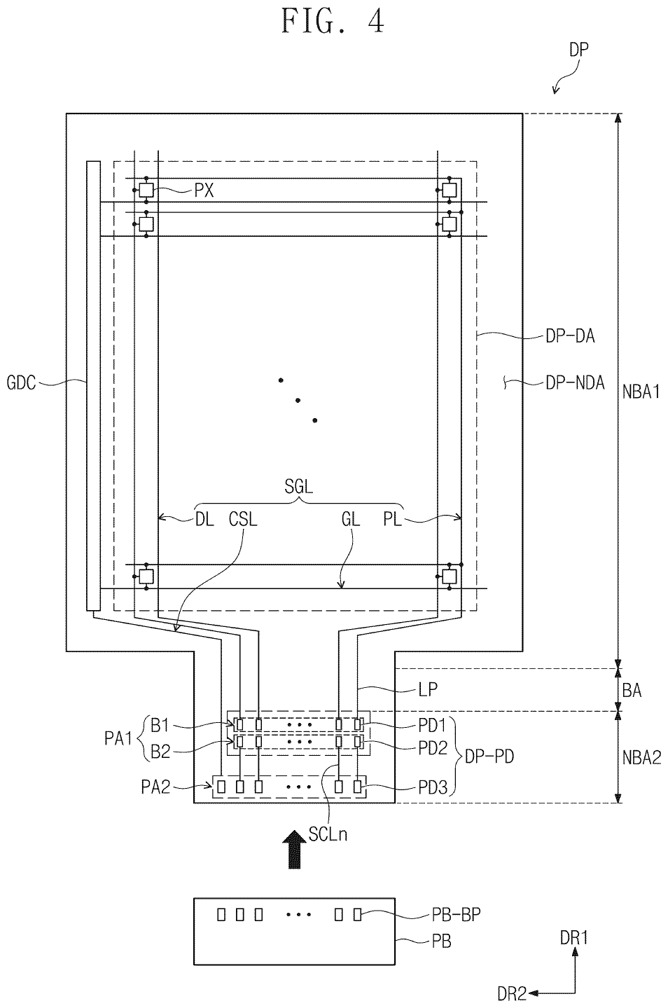

FIG. 4 is a plan view of a display panel DP according to one or more embodiments of the present disclosure.

Referring to FIG. 4, the display panel DP may include a plurality of pixels PX, a gate driving circuit GDC, a plurality of signal lines SGL, and a plurality of signal pads DP-PD.

The pixels PX may be arranged in a display region DP-DA. The pixels PX each include a light-emitting element and a pixel driving circuit connected thereto. In one or more embodiments, the light-emitting element may be an organic light-emitting element. The gate driving circuit GDC sequentially outputs gate signals to a plurality of gate lines GL (to be described in more detail later). A transistor of the gate driving circuit GDC and a transistor of a pixel PX may be formed through substantially the same process, for example, a low temperature polycrystalline silicon (LTPS) process or a low temperature polycrystalline oxide (LTPO) process. The display panel DP may further include another driving circuit which provides a light emission control signal to the pixels PX.

The signal lines SGL may include the gate lines GL, data lines DL, a power line PL, and a control signal line CSL. The gate lines GL may be each connected to a corresponding pixel PX among the pixels PX, and the data lines DL may be each connected to a corresponding pixel PX among the pixels PX. The power line PL may be connected to the pixels PX. The control signal line CSL may provide control signals to a scan driving circuit.

The signal lines SGL may overlap the display region DP-DA and a non-display region DP-NDA. The signal lines SGL may each include a line part LP. The signal lines SGL may further include a pad part. The line part LP may overlap the display region DP-DA and the non-display region DP-NDA. The pad part may be connected to an end of the line part LP.

The plurality of signal pads DP-PD may include first pads PD1, second pads PD2, and third pads PD3. A region in which the first and second pads PD1 and PD2 are arranged may be defined as a first pad region PA1, and a region in which the third pads PD3 are arranged may be defined as a second pad region PA2.

The first pad region PA1 may be a region overlapping the driving chip DC illustrated in FIG. 2A, and the second pad region PA2 may be a region overlapping the circuit board PB. The first pad region PA1 may include a first region B1 in which the first pads PD1 are arranged and a second region B2 in which the second pads PD2 are arranged. The first pad region PA1 and the second pad region PA2 may be arranged in the non-display region DP-NDA. The first pad region PA1 and the second pad region PA2 may be spaced and/or apart (e.g., spaced apart or separated) from each other in a first direction DR1. It is illustrated, as an example, that two pad rows are arranged in the first pad region PA1, but one or more embodiments of the present disclosure is not limited thereto, and at least three pad rows may be arranged in the first pad region PA1.

The first pads PD1 may be each connected to a corresponding data line DL among the data lines DL. In some embodiments, the first pads PD1 and the second pads PD2 may be electrically connected to each other. The second pads PD2 may be connected to the third pads PD3 via connection signal lines SCLn.

A circuit board PB may include a plurality of board bump electrodes PB-BP. The board bump electrodes PB-BP may be arranged in a second direction DR2. The board bump electrodes PB-BP of the circuit board PB may be in contact with and connected to the third pads PD3 of the second pad region PA2.

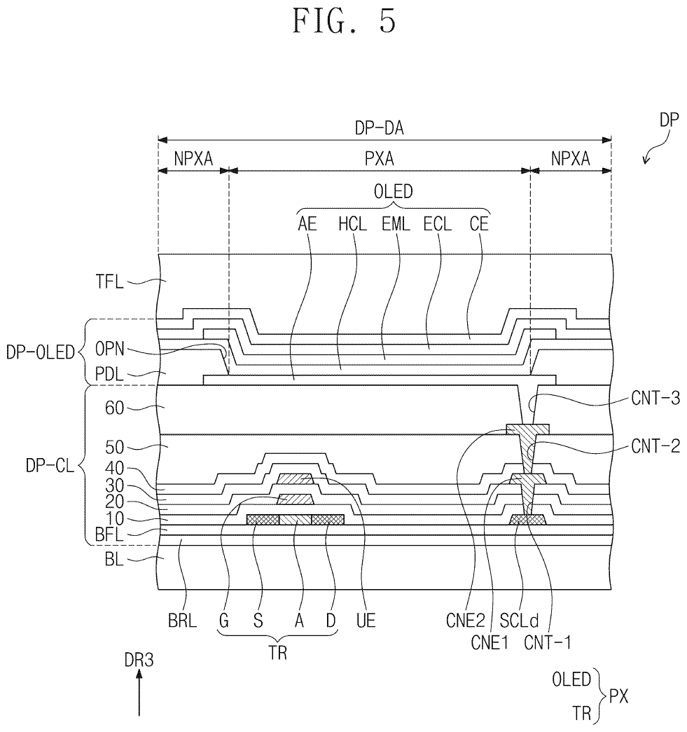

FIG. 5 is a cross-sectional view of a display panel DP illustrating a pixel PX according to one or more embodiments of the present disclosure.

Referring to FIG. 5, a display region DP-DA may include a light-emitting region PXA and a non-light-emitting region NPXA. Pixels PX may each include a light-emitting element OLED and a pixel driving circuit connected thereto. For example, the pixel PX may include a transistor TR and the light-emitting element OLED.

As an example, one transistor TR is illustrated in FIG. 5, but the present disclosure is not limited thereto. The pixel PX according to one or more embodiments may include two or more (e.g., seven) transistors TR and at least one capacitor, and the two or more (e.g., seven) transistors TR and a capacitor may be electrically connected to each other. However, the numbers of transistors TR and capacitors constituting the pixel PX are not limited to any one or more embodiments.

The display panel DP may include a plurality of insulating layers, a semiconductor pattern, a conductive pattern, a signal line, and/or the like. An insulating layer, a semiconductor layer, and a conductive layer may be formed through coating, depositing, and/or the like. Thereafter, the insulating layer, the semiconductor layer, and the conductive layer may be selectively patterned through photolithography. A semiconductor pattern, a conductive pattern, a signal line, and/or the like, included in a display element layer DP-OLED and a circuit element layer DP-CL may be formed through such processes.

A base layer BL may include a synthetic resin film. The base layer BL may have a multi-layered structure. For example, the base layer BL may have a triple-layered structure of a synthetic resin layer, an inorganic layer, and a synthetic resin layer. In some embodiments, the synthetic resin layer may be a polyimide-based resin layer, and a material thereof is not particularly limited. In addition, the base layer BL may include a glass substrate, a metal substrate, an organic/inorganic composite material substrate, and/or the like.

In one or more embodiments, the circuit element layer DP-CL may include a barrier layer BRL, a buffer layer BFL, first to sixth insulating layers 10 to 60, the transistor TR, a connection signal line SCLd, an upper electrode UE, a first connection electrode CNE1, and a second connection electrode CNE2.

At least one inorganic layer is arranged on an upper surface of the base layer BL. The inorganic layer may be formed of multiple layers. The barrier layer BRL may be arranged on the base layer BL. The buffer layer BFL may be arranged on the barrier layer BRL. The barrier layer BRL and the buffer layer BFL may each be an inorganic layer.

A semiconductor pattern is arranged on the buffer layer BFL. The semiconductor pattern may include polysilicon. However, the present disclosure is not limited thereto, and the semiconductor pattern may include amorphous silicon or metal oxide.

FIG. 5 illustrates a partial semiconductor pattern, and in a plan view, a semiconductor pattern may be further arranged in another region of the pixel PX. Semiconductor patterns may be arranged across the pixels PX in compliance with a certain rule. The semiconductor pattern has a different electrical property according to whether the semiconductor pattern is doped or not. The semiconductor pattern may include a first region and a second region. The first region may be doped with an N (negative)-type (kind) dopant or a P (positive)-type (kind) dopant. A P-type (kind) transistor includes a doped region doped with a P-type (kind) dopant.

The first region may have greater conductivity than the second region and substantially serve as an electrode or a signal line. The second region may be a region having low doping concentration or not doped and substantially correspond to an active (or channel) of a transistor. For example, a portion (e.g., a first portion) of the semiconductor pattern may be an active of a transistor, another portion (e.g., a second portion) thereof may be a source or drain of the transistor, and still another portion (e.g., a third portion) thereof may be a connection electrode or a connection signal line.

As illustrated in FIG. 5, a source S, an active A, and a drain D of the transistor TR may be formed from a semiconductor pattern.

FIG. 5 illustrates a portion of the connection signal line SCLd formed from a semiconductor pattern. In one or more embodiments, the connection signal line SCLd may be electrically connected to a drain of any one of transistors in the pixel PX.

The first insulating layer 10 is arranged on the buffer layer BFL. The first insulating layer 10 may cover the semiconductor pattern. The first insulating layer 10 may overlap the plurality of pixels PX in common (e.g., as a common layer). A gate G may be arranged on the first insulating layer 10. The gate G may be a portion of a metal pattern. The gate G may overlap the active A. The gate G may function as a mask in a process of doping the semiconductor pattern.

The second insulating layer 20 covering the gate G may be arranged on the first insulating layer 10. The second insulating layer 20 may overlap the pixels PX in common (e.g., as a common layer). The upper electrode UE may be arranged on the second insulating layer 20. The upper electrode UE may overlap the gate G of the transistor TR. The upper electrode UE may be a portion of a metal pattern. A portion of the gate G and the upper electrode UE overlapping the portion of the gate G may define a capacitor.

The third insulating layer 30 covering the upper electrode UE may be arranged on the second insulating layer 20. The first connection electrode CNE1 arranged on the third insulating layer 30 may be connected to the connection signal line SCLd through a contact hole CNT-1 penetrating the first to third insulating layers 10 to 30.

The fourth insulating layer 40 covering the first connection electrode CNE1 may be arranged on the third insulating layer 30. The first to fourth insulating layers 10 to 40 may each be an inorganic layer and/or an organic layer and may have a single- or multi-layered structure.

The first connection electrode CNE1 may be arranged on the fourth insulating layer 40 and covered with the fifth insulating layer 50. In one or more embodiments, a first connection electrode arranged on the third insulating layer 30 and covered with the fourth insulating layer 40 and a first connection electrode arranged on the fourth insulating layer 40 and covered with the fifth insulating layer 50 may be all included.

The fifth insulating layer 50 may be arranged on the fourth insulating layer 40. The fifth insulating layer 50 may be an organic layer. The second connection electrode CNE2 may be arranged on the fifth insulating layer 50. The second connection electrode CNE2 may be connected to the first connection electrode CNE1 through a contact hole CNT-2 penetrating the fourth insulating layer 40 and the fifth insulating layer 50.

The sixth insulating layer 60 covering the second connection electrode CNE2 may be arranged on the fifth insulating layer 50. The sixth insulating layer 60 may be an organic layer. A first electrode AE may be arranged on the sixth insulating layer 60. The first electrode AE may be connected to the second connection electrode CNE2 through a contact hole CNT-3 penetrating the sixth insulating layer 60.

The circuit element layer DP-CL may include a plurality of connection electrodes connected to transistors TR, and some of the plurality of connection electrodes may be arranged on different layers. In some embodiments, the first connection electrode CNE1 may extend and may be connected to the transistor TR. A position of the plurality of connection electrodes is not limited to any one or more embodiments.

The display element layer DP-OLED may include a pixel-defining film PDL and the light-emitting element OLED. A pixel opening OPN may be defined in the pixel-defining film PDL. The pixel opening OPN of the pixel-defining film PDL may expose at least a portion of the first electrode AE. In the present embodiment, the light-emitting region PXA may be defined to correspond to a partial region of the first electrode AE which is exposed by the pixel opening OPN.

A hole control layer HCL may be arranged in the light-emitting region PXA and the non-light-emitting region NPXA in common (e.g., as a common layer). The hole control layer HCL may include a hole transport layer and/or a hole injection layer. An emission layer EML may be arranged on the hole control layer HCL. The emission layer EML may be arranged in a region corresponding to the pixel opening OPN. For example, the emission layer EML may be separately formed in each of the pixels PX. However, the present disclosure is not limited thereto, and the emission layer EML may be formed in the plurality of pixels PX in common by using an open mask.

An electron control layer ECL may be arranged on the emission layer EML. The electron control layer ECL may include an electron transport layer and/or an electron injection layer. The hole control layer HCL and the electron control layer ECL may be formed in the pixels PX in common by using an open mask. A second electrode CE may be arranged on the electron control layer ECL. The second electrode CE may have an integrated form and may be arranged in the pixels PX in common. An upper insulating layer TFL may be arranged on the second electrode CE. The upper insulating layer TFL may include a plurality of thin films.

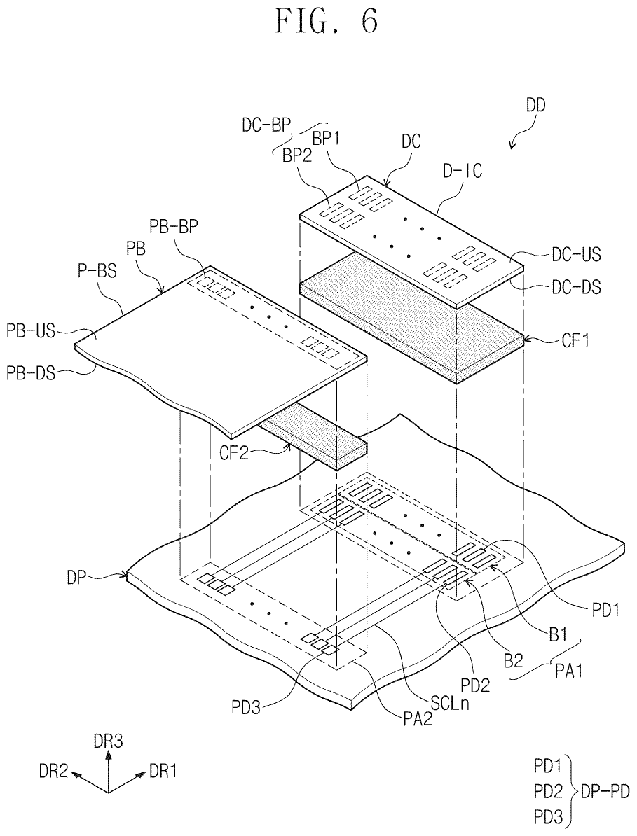

FIG. 6 is an enlarged exploded perspective view of a first pad region PA1 and a second pad region PA2 of a display device DD according to one or more embodiments of the present disclosure. For example, FIG. 6 illustrates that a driving chip DC and a circuit board PB are disassembled from a display panel DP. Because first pads PD1, second pads PD2, connection signal lines SCLn, and third pads PD3 illustrated in FIG. 6 may each independently be the same as the first pads PD1, the second pads PD2, the connection signal lines SCLn, and the third pads PD3 illustrated in FIG. 4, description thereof will not be provided or will be provided briefly.

Referring to FIGS. 4 and 6, the driving chip DC may be bonded to a first pad region PA1 through a first adhesive layer CF1. The circuit board PB may be bonded to a second pad region PA2 through a second adhesive layer CF2. The first and second adhesive layers CF1 and CF2 may each include an adhesive synthetic resin. The first and second adhesive layers CF1 and CF2 may be each a non-conductive film. For example, the first and second adhesive layers CF1 and CF2 may not include (e.g., may exclude) a (e.g., any) conductive ball (e.g., conductive particles) and may include only an adhesive synthetic resin.

The driving chip DC may include a driving integrated circuit D-IC and chip bump electrodes DC-BP mounted in the driving chip DC. The driving integrated circuit D-IC may include an upper surface DC-US and a lower surface DC-DS, and the lower surface DC-DS may be a surface facing the first and second pads PD1 and PD2. The chip bump electrodes DC-BP may be arranged on the lower surface DC-DS of the driving integrated circuit D-IC.

The chip bump electrodes DC-BP may include first bumps BP1 electrically connected respectively to the first pads PD1 and second bumps BP2 electrically connected respectively to the second pads PD2. The first bumps BP1 may be arranged along a second direction DR2, and the second bumps BP2 may be spaced and/or apart (e.g., spaced apart or separated) from the first bumps BP1 in a first direction DR1 and arranged along the second direction DR2.

The driving chip DC may receive first signals from the outside through the second pads PD2 and the second bumps BP2. The driving chip DC may provide second signals generated on the basis of the first signals to the first pads PD1 through the first bumps BP1. For example, the driving chip DC may include a data driving circuit. A first signal may be an image signal that is a digital signal applied (e.g., provided) from the outside, and a second signal may be a data signal that is an analog signal. The driving chip DC may generate an analog voltage corresponding to a gray scale value of an image signal. A data signal may be provided to a pixel PX through a data line DL illustrated in FIG. 4.

In some embodiments, the first bumps BP1 and the second bumps BP2 may protrude from the lower surface DC-DS of the driving integrated circuit D-IC and may be exposed to the outside. When the first adhesive layer CF1 is cured, the first pads PD1 and the first bumps BP1 may be fixed in a state of being in contact with each other, and the second pads PD2 and the second bumps BP2 may be fixed in a state of being in contact (e.g., electrical and/or physical contact) with each other.

The circuit board PB may include a base layer P-BS and board bump electrodes PB-BP mounted in the circuit board PB. The circuit board PB may include an upper surface PB-US and a lower surface PB-DS, and the lower surface PB-DS may be a surface facing the third pads PD3. The board bump electrodes PB-BP may be arranged on the lower surface PB-DS of the base layer P-BS. The board bump electrodes PB-BP may be electrically connected respectively to the third pads PD3. The board bump electrodes PB-BP may be arranged along the second direction DR2. The circuit board PB may provide an image signal, a driving voltage, and any other control signal to the driving chip DC.

In some embodiments, the board bump electrodes PB-BP may protrude from the lower surface PB-DS of the base layer P-BS and may be exposed to the outside. When the second adhesive layer CF2 is cured, the third pads PD3 and the board bump electrodes PB-BP may be fixed in a state of being in contact (e.g., electrical and/or physical contact) with each other.

An electronic component may include a substrate and a bump electrode arranged on a lower side of the substrate. In a case in which the electronic component corresponds to the driving chip DC, the substrate may correspond to the driving integrated circuit D-IC of the driving chip DC, and the bump electrode may correspond to a chip bump electrode DC-BP. In one or more embodiments, in a case in which the electronic component corresponds to the circuit board PB, the substrate may correspond to the base layer P-BS of the circuit board PB, and the bump electrode may correspond to a board bump electrode PB-BP.

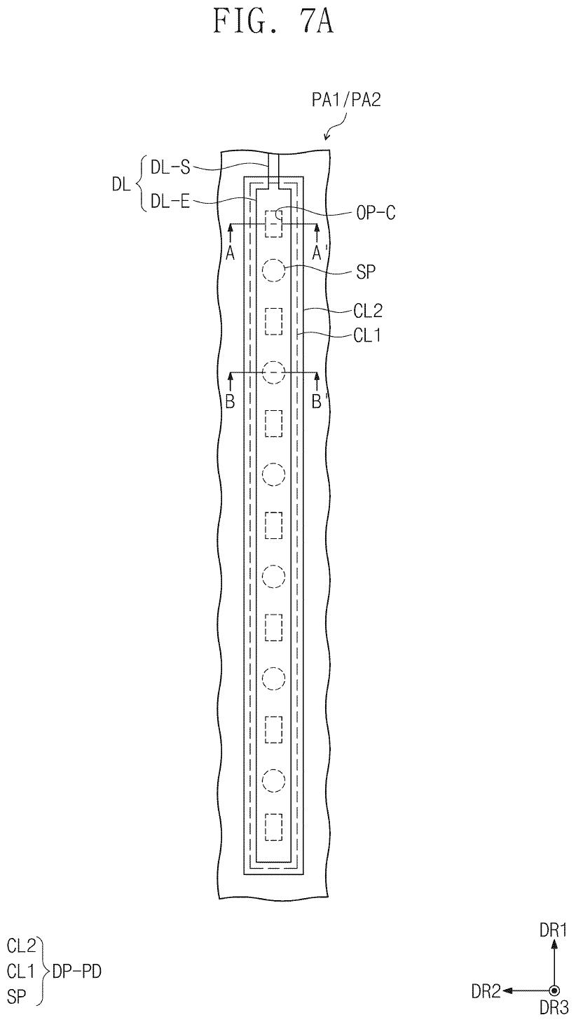

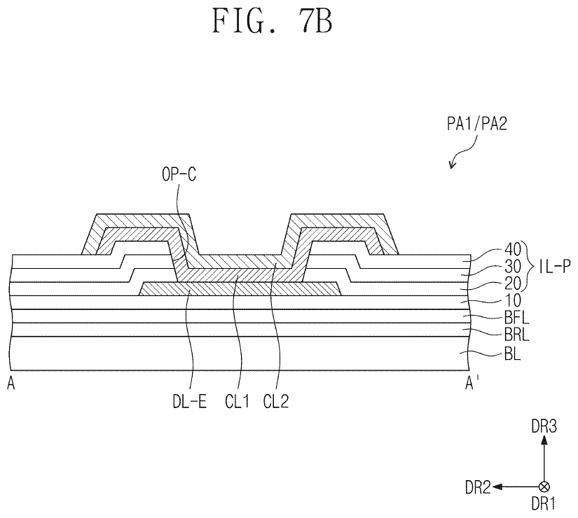

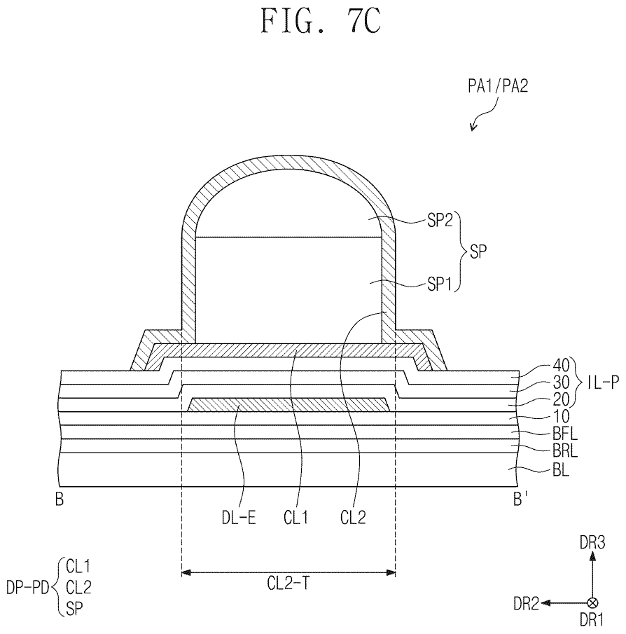

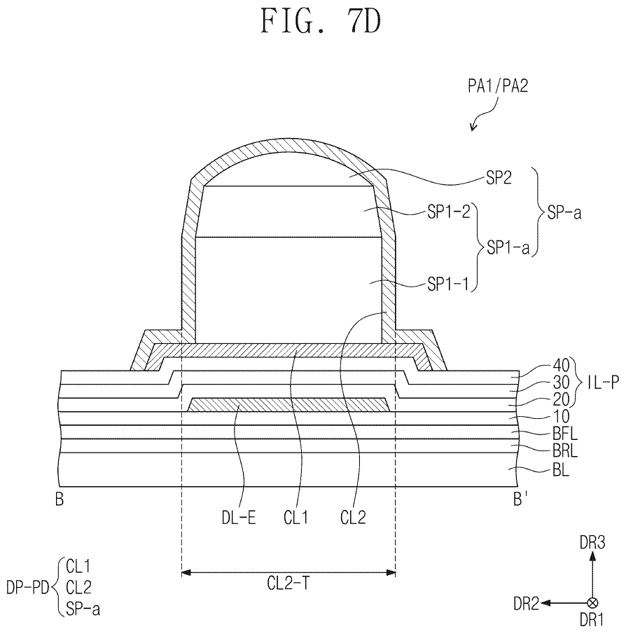

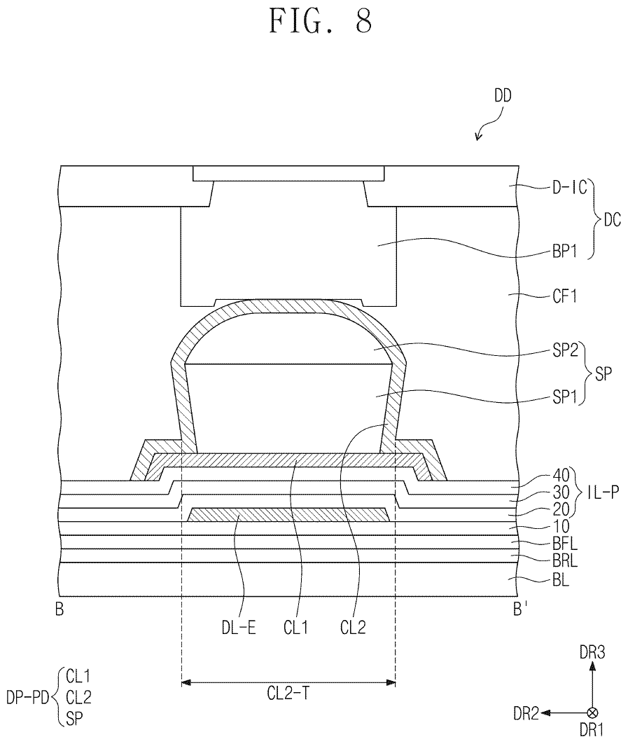

FIG. 7A is a schematic plan view of a first pad region PA1 and a second pad region PA2 according to one or more embodiments of the present disclosure. FIGS. 7B to 7D each are a cross-sectional view of the first pad region PA1 and the second pad region PA2 according to one or more embodiments of the present disclosure. FIG. 8 is a cross-sectional view illustrating a bonding structure of a display device DD according to one or more embodiments of the present disclosure. FIG. 7B is a cross-sectional view of the first pad region PA1 and the second pad region PA2 taken along the line A-A′ of FIG. 7A, and FIGS. 7C and 7D each are a cross-sectional view of the first pad region PA1 and the second pad region PA2 taken along the line B-B′ of FIG. 7A.

A signal pad DP-PD (or a signal pad structure) illustrated in FIGS. 7A to 8 may be any one of the first to third pads PD1 to PD3 described with reference to FIGS. 4 and 6. FIG. 7A illustrates a data line DL including an end portion DL-E and a line portion DL-S which are different in width as an example of a signal line SCL, but the present disclosure is not limited thereto. Here, a width may refer to a length or width of the end portion DL-E or the line portion DL-S in a second direction DR2. In some embodiments, the signal line SCL may be another signal line SCL other than the data line DL and may have a substantially uniform width without being divided into the end portion DL-E and the line portion DL-S. The end portion DL-E may correspond to the pad part described with reference to FIG. 4.

Hereinafter, the first pad region PA1 and the second pad region PA2 will be described with a focus on a first pad region PA1 in which the data line DL is arranged. Description of the first pad region PA1 may be equally applied to a second pad region PA2 except that a connection signal line SCLn (see FIG. 4) is arranged in the second pad region PA2 instead of the data line DL.

Referring to FIG. 7A, the signal pad DP-PD may include a first conductive pattern CL1, a second conductive pattern CL2, and at least one insulating pattern SP. The first conductive pattern CL1 may be connected to the end portion DL-E of the data line DL through at least one contact hole OP-C. FIG. 7A illustrates, as an example, the signal pad DP-PD including seven contact holes OP-C and six insulating patterns SP, and the numbers of contact holes OP-C and insulating patterns SP are not limited thereto.

In a plan view, the end portion DL-E may have a shape extending in a first direction DR1. For example, a length or a width of the end portion DL-E in the first direction DR1 may be greater than a length or a width of the end portion DL-E in a second direction DR2.

In a plan view, the contact holes OP-C may overlap the end portion DL-E. The contact holes OP-C may be arranged along the first direction DR1. The contact holes OP-C may be arranged to be spaced and/or apart (e.g., spaced apart or separated) from each other in the first direction DR1. In a plan view, a portion of the first conductive pattern CL1 may overlap the contact holes OP-C.

In a plan view, the insulating patterns SP may overlap the second conductive pattern CL2. In a plan view, the insulating patterns SP may be arranged to be spaced and/or apart (e.g., spaced apart or separated) from the contact holes OP-C. In the present embodiment, the insulating patterns SP may be arranged along the first direction DR1. The insulating patterns SP may be arranged to be spaced and/or apart (e.g., spaced apart or separated) from each other in the first direction DR1.

In the present embodiment, the insulating patterns SP may be arranged between adjacent contact holes OP-C. FIG. 7A illustrates, as an example, six insulating patterns SP respectively arranged on six planes between seven contact holes OP-C, but arrangement relationship is not limited thereto.

FIG. 7A illustrates, as an example, that the insulating patterns SP each have a circular shape in a plan view, but the present disclosure is not limited thereto. A planar shape of each of the insulating patterns SP may be changed into an elliptical shape. In addition, shapes of the insulating patterns SP are not limited to all being the same.

Referring to FIGS. 7B to 7D, the end portion DL-E may be arranged on a first insulating layer 10. The end portion DL-E may be arranged at the same layer as the gate G illustrated in FIG. 5. The end portion DL-E may be formed through substantially the same process as the gate G (see FIG. 5). The end portion DL-E may include the same material as the gate G (see FIG. 5).

However, a position of the end portion DL-E is not limited thereto. In some embodiments, the end portion DL-E may be arranged at the same layer, include the same material, and have the same stacked structure as the upper electrode UE illustrated in FIG. 5. In one or more embodiments, some of a plurality of signal lines SCL may be formed through substantially the same process as the gate G (see FIG. 5), and others of the plurality of signal lines SCL may be formed through substantially the same process as the upper electrode UE (see FIG. 5).

The data line DL may be arranged on one layer and have an integrated form, but the present disclosure is not limited thereto. One data line DL may include a plurality of portions arranged on different layers. For example, the line portion DL-S may include at least two portions.

The first conductive pattern CL1 may be arranged on a fourth insulating layer 40. The first conductive pattern CL1 may be connected to the end portion DL-E through a contact hole OP-C penetrating second to fourth insulating layers 20, 30, and 40. For example, the first conductive pattern CL1 may be in contact with the end portion DL-E through the contact hole OP-C. The second to fourth insulating layers 20, 30, and 40 may be formed through substantially the same process as the second to fourth insulating layers 20, 30, and 40 of the display region DP-DA illustrated in FIG. 5. Herein, insulating layers arranged between the end portion DL-E and the first conductive pattern CL1 may be defined as a pad insulating layer IL-P. In the present embodiment, the second to fourth insulating layers 20, 30, and 40 may be defined as the pad insulating layer IL-P. A stacked structure of the pad insulating layer IL-P may be changed according to a stacked structure of the circuit element layer DP-CL (see FIG. 5). In one or more embodiments, the contact hole OP-C may be defined by more or fewer insulating layers than the second to fourth insulating layers 20, 30, and 40.

The first conductive pattern CL1 and the end portion DL-E may be distinguished by the pad insulating layer IL-P (for example, the second to fourth insulating layers 20, 30, and 40) arranged therebetween.

The second conductive pattern CL2 may be arranged on the first conductive pattern CL1. A region of the second conductive pattern CL2 not overlapping an insulating pattern SP may be in contact with the first conductive pattern CL1. A region of the second conductive pattern CL2 overlapping the insulating pattern SP may be in contact with the insulating pattern SP.

In one or more embodiments, the first conductive pattern CL1 may be formed through substantially the same process as the first connection electrode CNE1 described with reference to FIG. 5, and the second conductive pattern CL2 may be formed through substantially the same process as the second connection electrode CNE2 described with reference to FIG. 5. The first conductive pattern CL1 may include the same material as the first connection electrode CNE1 (see FIG. 5), and the second conductive pattern CL2 may include the same material as the second connection electrode CNE2 (see FIG. 5). FIGS. 7B to 7D illustrates, as an example, one or more embodiments in which the first conductive pattern CL1 is arranged on the fourth insulating layer 40. According to one or more embodiments, the first conductive pattern CL1 may be arranged on the third insulating layer 30, and in this case, the fourth insulating layer 40 may not be arranged in the first pad region PA1 and the second pad region PA2. However, the present disclosure is not limited thereto, and/or a (e.g., any suitable) combination of connection electrodes which are formed through substantially the same process as the first and second conductive patterns CL1 and CL2 may be variously selected according to a stacked structure of the circuit element layer DP-CL (see FIG. 5) as long as the first and second conductive patterns CL1 and CL2 of different layers are capable of being provided.

It is illustrated, as an example, that in a plan view, the second conductive pattern CL2 has a greater area size than the first conductive pattern CL1, and an edge of the second conductive pattern CL2 is arranged further outwards than an edge of the first conductive pattern CL1 and covers the edge of the first conductive pattern CL1 (e.g., the second conductive pattern CL2 has a larger area than the first conductive pattern CL1 and extends beyond its edges, covering them), but the present disclosure is not limited thereto. In some embodiments, the second conductive pattern CL2 may have substantially the same area size as the first conductive pattern CL1, and the edge of the second conductive pattern CL2 may be substantially aligned with the edge of the first conductive pattern CL1.

A portion of the second conductive pattern CL2 may include a portion overlapping the insulating pattern SP in a plan view. The insulating pattern SP may be arranged between the first conductive pattern CL1 and the second conductive pattern CL2 in a cross-sectional view. The insulating pattern SP may be arranged on the first conductive pattern CL1 and covered with the second conductive pattern CL2. The second conductive pattern CL2 may cover an upper surface of the insulating pattern SP. The insulating pattern SP may be arranged on an inner side of each of the first conductive pattern CL1 and the second conductive pattern CL2 in a plan view.

In one or more embodiments, the second conductive pattern CL2 may have a multi-layered structure. For example, the second conductive pattern CL2 may have a triple-layered structure of a first layer, a second layer, and a third layer which are sequentially stacked. The second layer may have higher conductivity than the first layer and the third layer. For example, the first layer and the third layer may include titanium (Ti), and the second layer may include aluminum (Al).

The upper surface of the insulating pattern SP may be defined as a portion, having a curvature, of a surface of the insulating pattern SP being in contact with the second conductive pattern CL2. A lower surface of the insulating pattern SP may be defined as a surface of the insulating pattern SP being in contact with the first conductive pattern CL1. A side surface of the insulating pattern SP may be defined as a surface connecting the upper surface and the lower surface. For example, the side surface of the insulating pattern SP may be a portion, being normal (e.g., perpendicular) to the lower surface, of a surface of the insulating pattern SP being in contact with the second conductive pattern CL2.

The insulating pattern SP includes a first portion SP1 and a second portion SP2. The first portion SP1 is arranged on the first conductive pattern CL1. The first portion SP1 may be directly arranged on the first conductive pattern CL1. A lower surface of the first portion SP1 may correspond to the lower surface of the insulating pattern SP. A side surface of the first portion SP1 may be in contact with the second conductive pattern CL2. The side surface of the first portion SP1 may correspond to the side surface of the insulating pattern SP. The second portion SP2 is arranged on the first portion SP1. The second portion SP2 may be directly arranged on the first portion SP1. An upper surface of the second portion SP2 may be in contact with the second conductive pattern CL2. The upper surface of the second portion SP2 may correspond to the upper surface of the insulating pattern SP. A lower surface of the second portion SP2 may correspond to an upper surface of the first portion SP1. The lower surface of the second portion SP2 and the upper surface of the first portion SP1 may be substantially identical surfaces that match each other (e.g., in shape and size). That is, the upper surface of the first portion SP1 is congruent to the lower surface of the second portion SP2.

The first portion SP1 may have a pillar shape. For example, the first portion SP1 may have a cylindrical shape or a polyprismatic shape. A pillar shape may refer to a shape in which an upper surface and a lower surface are substantially flat and a side surface is substantially normal (e.g., perpendicular) to the lower surface. For example, the upper surface and the lower surface of the first portion SP1 may be substantially parallel to a plane defined by a first direction DR1 and a second direction DR2. In addition, the side surface of the first portion SP1 may be substantially parallel to a third direction DR3.

A planar shape of the first portion SP1 may be a circular shape like a shape of the insulating pattern SP illustrated in FIG. 7A. However, the planar shape of the first portion SP1 is not limited thereto and may be, for example, an elliptical shape or a polygonal shape.

A cross-sectional shape of the first portion SP1 may be a rectangular shape as illustrated in FIG. 7C. However, the cross-sectional shape of the first portion SP1 is not limited thereto and may be, for example, a square shape. A height (length in the third direction DR3) of the first portion SP1 may be, for example, about 0.5 μm to about 3.5 μm. A width (length in the second direction DR2) of the first portion SP1 may be, for example, about 1.6 μm to about 4.6 μm. The height and width of the first portion SP1 are not limited to the above examples and may vary according to a process and a specific design.

The second portion SP2 may have a dome shape. For example, the second portion SP2 may have a shape in which an upper surface is hemispherical. A dome shape may refer to a shape in which a lower surface is substantially flat and an upper surface includes an upwardly convex curved line. For example, a lower surface of the second portion SP2 may be substantially parallel to a plane defined by the first direction DR1 and the second direction DR2. In addition, the upper surface of the second portion SP2 may have a shape that is convex in the third direction DR3.

A planar shape of the second portion SP2 may be a circular shape. However, the planar shape of the second portion SP2 is not limited thereto and may be, for example, an elliptical shape or a polygonal shape.

A cross-sectional shape of the second portion SP2 may be a shape in which an upper surface is an upwardly convex curved line and a lower surface is a straight line as illustrated in FIG. 7C. FIG. 7C illustrates that a width (length of a lower surface in the second direction DR2) of the second portion SP2 is greater than a height (length in the third direction DR3) of the second portion SP2, but the shape of the second portion SP2 is not limited thereto. For example, the width (length of the lower surface in the second direction DR2) of the second portion SP2 may be smaller than the height (length in the third direction DR3) of the second portion SP2. A height of the second portion SP2 may be, for example, about 0.3 μm to about 2.3 μm. The height of the second portion SP2 is not limited to the above examples and may vary according to a process and a specific design.

Because the first portion SP1 has a pillar shape, and the second portion SP2 arranged on the first portion SP1 has a dome shape, if (e.g., when) pressure is applied to the insulating pattern SP in the third direction DR3, the first portion SP1 may support pressure and maintain restoring force, the second portion SP2 may allow a resin of an adhesive film to be discharged during bonding, and pressure may be concentrated on the second portion SP2. Thus, if (e.g., when) press bonding an electronic component such as the driving chip DC to the display panel DP, pressure may be concentrated on the second portion SP2, and thus the amount of deformation of the second portion SP2 may be increased, and a thin film (for example, the third layer described above) included in the second conductive pattern CL2 arranged on the second portion SP2 may be easily torn. Because the thin film (the third layer) included in the second conductive pattern CL2 is easily torn, the second layer arranged under the third layer may be easily exposed, and contact between the second layer and a bump BP1 (see FIG. 8) may be facilitated.

The first portion SP1 and the second portion SP2 may each include a polymer. The first portion SP1 and the second portion SP2 may each include a thermosetting polymer. However, the present disclosure is not limited thereto, and the insulating pattern SP may include a thermoplastic polymer. A modulus (e.g., elastic modulus) of the first portion SP1 may be greater than a modulus (e.g., elastic modulus) of the second portion SP2. For example, a modulus of the first portion SP1 may be about 6 GPa to about 7 GPa, and a modulus of the second portion SP2 may be about 2.5 GPa to about 3 GPa.

Because the modulus of the first portion SP1 is greater than the modulus of the second portion SP2, if (e.g., when) pressure is applied to the insulating pattern SP in the third direction DR3, a deformation rate of the first portion SP1 may be smaller, and a deformation rate of the second portion SP2 may be greater. Thus, if (e.g., when) press bonding an electronic component such as the driving chip DC to the display panel DP, pressure may be concentrated on the second portion SP2, and thus the amount of deformation of the second portion SP2 may be increased, and a thin film (for example, the third layer described above) included in the second conductive pattern CL2 arranged on the second portion SP2 may be easily torn. Because the thin film (the third layer) included in the second conductive pattern CL2 is easily torn, the second layer arranged under the third layer may be easily exposed, and contact between the second layer and a bump BP1 (see FIG. 8) may be facilitated.

The first portion SP1 may be formed from a negative photoresist material. A negative photoresist material may refer to a material of which an unexposed portion dissolves in a developer. The second portion SP2 may be formed from a positive photoresist material. A positive photoresist material may refer to a material of which an exposed portion dissolves in a developer.

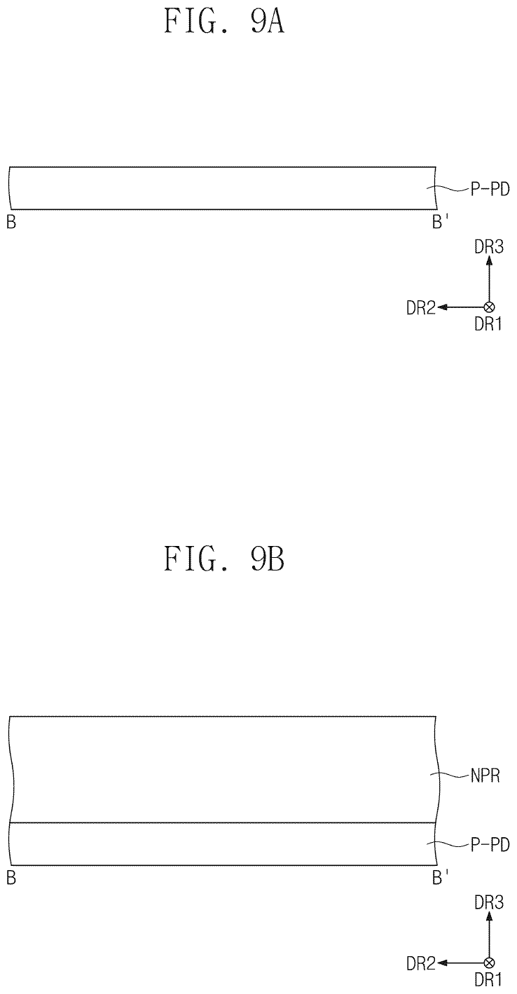

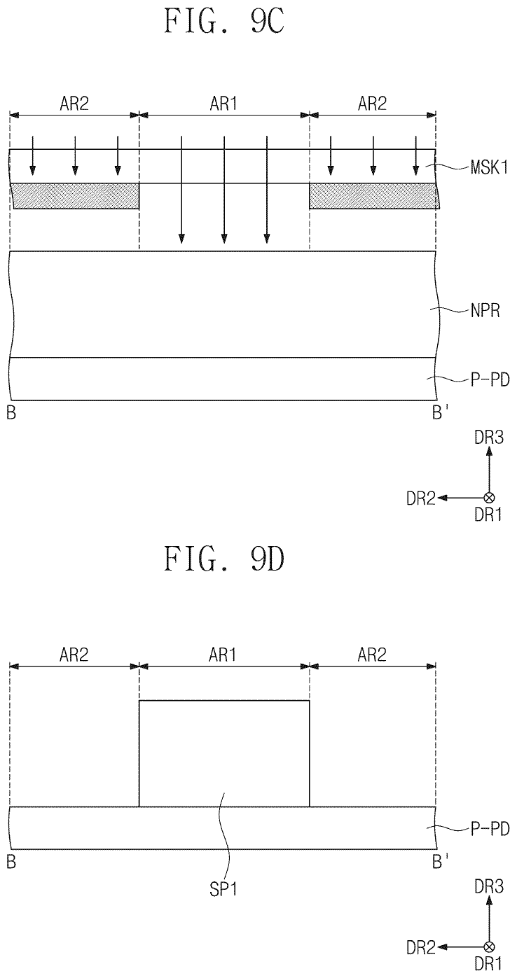

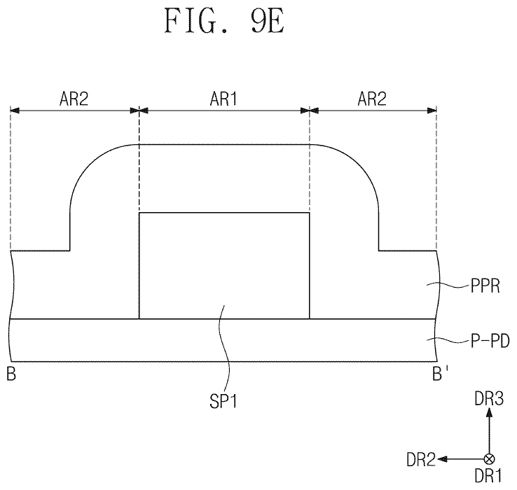

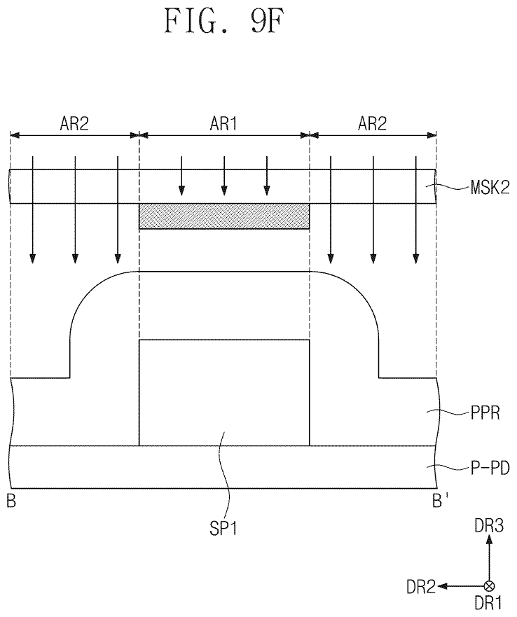

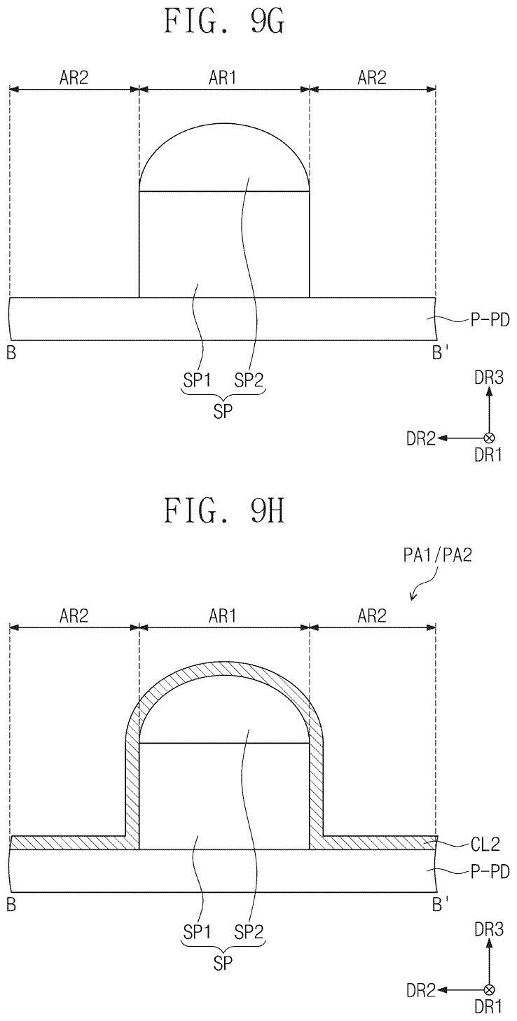

The first portion SP1 may be formed from a negative photoresist material, and thus may be formed in a pillar shape without an additional process step (e.g., act or task). The second portion SP2 may be formed from a positive photoresist material, and thus may be formed in a dome shape without an additional process step (e.g., act or task). For example, the first portion SP1 is formed from a negative photoresist material, which refers to that the unexposed portion dissolves in a developer, resulting in a pillar shape without additional processing steps (e.g., acts or tasks). The second portion SP2 is formed from a positive photoresist material, where the exposed portion dissolves in a developer, resulting in a dome shape without additional processing steps (e.g., acts or tasks). A process of forming the first portion SP1 and the second portion SP2 will be described in more detail with reference to FIGS. 9A to 9H.

A portion of the second conductive pattern CL2 covering the insulating pattern SP may further protrude in the third direction DR3 from the first conductive pattern CL1 compared to the other portion of the second conductive pattern CL2. A protruding portion of the second conductive pattern CL2 may be referred to as a protruding portion CL2-T. The second conductive pattern CL2 may be in contact with an upper surface of the first conductive pattern CL1 not overlapping the insulating pattern SP and the upper surface of the insulating pattern SP. The protruding portion CL2-T of the second conductive pattern CL2 may correspond to a portion being in contact with the upper surface of the insulating pattern SP.

Referring to FIG. 7D, a first portion SP1-a of an insulating pattern SP-a may have a multi-layered structure. The first portion SP1-a may include a (1-1)-th portion SP1-1 arranged on the first conductive pattern CL1 and a (1-2)-th portion SP1-2 arranged on the (1-1)-th portion SP1-1. FIG. 7D illustrates, as an example, that the first portion SP1-a has a double-layered structure, but the present disclosure is not limited thereto, for example, the first portion SP1-a may have a structure of at least three layers.

The (1-1)-th portion SP1-1 may have a pillar shape. The (1-2)-th portion SP1-2 may have a pillar shape. A second portion SP2 may have a dome shape. The (1-1)-th portion SP1-1 and the (1-2)-th portion SP1-2 may be each formed from a negative photoresist material, and thus may be formed in a pillar shape without an additional process. The second portion SP2 may be formed from a positive photoresist material, and thus may be formed in a dome shape without an additional process. In one or more embodiments, the (1-1)-th portion SP1-1 may be formed from a negative photoresist material, and the (1-2)-th portion SP1-2 and the second portion SP2 may be each formed from a positive photoresist material.

Each of a modulus (e.g., elastic modulus) of the (1-1)-th portion SP1-1 and a modulus (e.g., elastic modulus) of the (1-2)-th portion SP1-2 may be greater than a modulus (e.g., elastic modulus) of the second portion SP2. Accordingly, if (e.g., when) pressure is applied in the third direction DR3, the (1-1)-th portion SP1-1 and the (1-2)-th portion SP1-2 may support pressure and maintain restoring force, and pressure may be concentrated on the second portion SP2. The modulus (e.g., elastic modulus) of the (1-1)-th portion SP1-1 may be greater than the modulus (e.g., elastic modulus) of the (1-2)-th portion SP1-2, but the present disclosure is not limited thereto.

FIG. 8 illustrates, as an example, a driving chip DC as an electronic component. FIG. 8 illustrates a state in which a first bump BP1 among the chip bump electrodes DC-BP (see FIG. 6) of the driving chip DC is in contact with a first pad PD1 (see FIG. 6). The first pad PD1 (see FIG. 6) is illustrated as a signal pad DP-PD in FIG. 8.

The first bump BP1 of the driving chip DC may penetrate a first adhesive layer CF1 and may be in contact with a second conductive pattern CL2 of the signal pad DP-PD by a bonding process. The display device DD of the present disclosure may not include (e.g., may exclude) a conductive ball (e.g., conductive particles), thereby preventing or reducing short circuit caused by a conductive ball and/or energization failure in a case in which a conductive ball is not arranged between the signal pad DP-PD and a bump electrode, even if signal pads DP-PD are densely arranged, thus being advantageous or desirable in providing a high-resolution panel.

In an insulating pattern SP according to the present disclosure, a first portion SP1 may be formed from a negative photoresist material, and thus may be formed in a pillar shape without an additional process step (e.g., act or task). A second portion SP2 may be formed from a positive photoresist material, and thus may be formed in a dome shape without an additional process step (e.g., act or task).

Because the first portion SP1 has a pillar shape, and the second portion SP2 arranged on the first portion SP1 has a dome shape, if (e.g., when) pressure is applied to the insulating pattern SP in a third direction DR3, the first portion SP1 may support pressure and maintain restoring force, the second portion SP2 may allow a resin of an adhesive film to be discharged during bonding, and pressure may be concentrated on the second portion SP2.

In addition, because a modulus (e.g., elastic modulus) of the first portion SP1 is greater than a modulus (e.g., elastic modulus) of the second portion SP2, if (e.g., when) pressure is applied to the insulating pattern SP in the third direction DR3, as illustrated in FIG. 8, a deformation rate of the first portion SP1 may be smaller, and a deformation rate of the second portion SP2 may be greater. Thus, if (e.g., when) press bonding an electronic component such as the driving chip DC to the display panel DP, pressure may be concentrated on the second portion SP2, and thus the amount of deformation of the second portion SP2 may be increased, and a thin film (for example, the third layer described above) included in the second conductive pattern CL2 arranged on the second portion SP2 may be easily torn.

Because the thin film (e.g., the third layer) included in the second conductive pattern CL2 is easily torn, the second layer arranged under the third layer may be easily exposed, and contact between the second layer and the bump BP1 may be facilitated. For example, in the display device DD including the display panel DP according to the present disclosure, bonding reliability may be improved, and thus initial resistance and reliability resistance may be improved.

FIGS. 9A to 9H each are a cross-sectional view illustrating a step (e.g., act or task) of a manufacturing method of a pad region according to one or more embodiments of the present disclosure.

For convenience of description, FIGS. 9A to 9H each illustrate a cross-section taken along the line B-B′ of FIG. 7A. In FIGS. 9A to 9H, the above description made with reference to FIGS. 4 to 7C may be equally applied to the same component, and detailed description thereof will not be provided.

A manufacturing method of a display panel DP of one or more embodiments includes providing a preliminary signal pad P-PD and forming an insulating pattern SP on the preliminary signal pad P-PD.

FIG. 9A schematically illustrates the providing of the preliminary signal pad P-PD. The preliminary signal pad P-PD may include the first conductive pattern CL1 (see FIG. 7C). The preliminary signal pad P-PD may further include the base layer BL (see FIG. 7C), the barrier layer BRL (see FIG. 7C), the buffer layer BFL (see FIG. 7C), the first to fourth insulating layers 10, 20, 30, and 40 (see FIG. 7C), and the end portion DL-E (see FIG. 7C) of the signal line SCL.

FIGS. 9B to 9G each schematically illustrate the forming of the insulating pattern SP on the preliminary signal pad P-PD. The forming of the insulating pattern SP includes forming a first portion SP1 and forming a second portion SP2.

FIGS. 9B to 9D each schematically illustrate forming the first portion SP1 on the preliminary signal pad P-PD. The forming of the first portion SP1 may be forming the first portion SP1 on the preliminary signal pad P-PD in a first region AR1 by using a negative photoresist material NPR.

The first region AR1 may refer to a region in which the insulating pattern SP is to be formed in a plan view. A second region AR2 may refer to a region, being adjacent to and around (e.g., surrounding) the first region AR1, in which the insulating pattern SP is not to be formed in a plan view. The first region AR1 may have a circular shape, an elliptical shape, or a polygonal shape in a plan view.

Referring to FIG. 9B, the forming of the first portion SP1 may include applying the negative photoresist material NPR onto the preliminary signal pad P-PD. The negative photoresist material NPR may coat an entire surface of the preliminary signal pad P-PD, but the present disclosure is not limited thereto and may coat a partial region of the preliminary signal pad P-PD.

Referring to FIG. 9C, the forming of the first portion SP1 may include exposing a first region AR1 of the negative photoresist material NPR that is applied. A first mask MSK1 may be applied in the exposing of the first region AR1. The first mask MSK1 may be to transmit light in the first region AR1 and block light in the second region AR2. Light may be ultraviolet light in the exposing.

Referring to FIG. 9D, the forming of the first portion SP1 may include forming the first portion SP1 in the first region AR1 by developing and curing the negative photoresist material NPR. The negative photoresist material NPR of an exposed portion, that is, the negative photoresist material NPR of the first region AR1 may remain. The negative photoresist material NPR of an unexposed portion, that is, the negative photoresist material NPR of the second region AR2 may be removed by a developer. The first portion SP1 may be formed from the negative photoresist material NPR, and thus may be formed in a pillar shape without an additional process.

FIGS. 9E to 9G each schematically illustrate forming the second portion SP2 on the first portion SP1. The forming of the second portion SP2 may be forming the second portion SP2 on the first portion SP1 by using a positive photoresist material PPR.

Referring to FIG. 9E, the forming of the second portion SP2 may include applying the positive photoresist material PPR onto the preliminary signal pad P-PD and the first portion SP1. While covering the first portion SP1, the positive photoresist material PPR may coat the preliminary signal pad P-PD on which the first portion SP1 is not formed.

Referring to FIG. 9F, the forming of the second portion SP2 may include exposing a second region AR2 of the positive photoresist material PPR that is applied. A second mask MSK2 may be applied in the exposing of the second region AR2. The second mask MSK2 may block light in a first region AR1 and transmit light in the second region AR2. Light may be ultraviolet light in the exposing.

Referring to FIG. 9G, the forming of the second portion SP2 may include forming the second portion SP2 on the first portion SP1 by developing and curing the positive photoresist material PPR. The positive photoresist material PPR of an exposed portion, that is, the positive photoresist material PPR of the second region AR2 may be removed. The positive photoresist material PPR of an unexposed portion, that is, the positive photoresist material PPR of the first region AR1 may remain. The second portion SP2 may be formed from the positive photoresist material PPR, and thus may be formed in a dome shape without an additional process.

Referring to FIG. 9H, the manufacturing method of a display panel DP of one or more embodiments may further include forming a second conductive pattern CL2. The content described above with reference to FIG. 7C may be equally applied to the second conductive pattern CL2, and thus description thereof will not be provided.

According to the manufacturing method of a display panel according to the present disclosure, a pillar shape and a dome shape on the pillar shape may be provided without an additional process. Accordingly, processability may be improved. In addition, it is described above that because the insulating pattern SP includes the first portion SP1 in a pillar shape and the second portion SP2 in a dome shape, bonding reliability may be improved, and because a modulus (e.g., elastic modulus) of the first portion SP1 is greater than a modulus (e.g., elastic modulus) of the second portion SP2, bonding reliability may be further improved.

According to the description above, a display panel of the present disclosure may include an insulating pattern including a pillar and a dome, and thus bonding reliability may be improved. In addition, the display panel of the present disclosure may include the insulating pattern including materials having different moduli (e.g., elastic moduli), and thus bonding reliability may be improved.

In addition, a manufacturing method of a display panel of the present disclosure may not require an additional process for providing curvature to an upper surface of the insulating pattern, and thus processability may be improved.

For example, according to a manufacturing method of a display panel described in the present disclosure, a pillar shape and a dome shape on the pillar shape can be provided without additional processing steps, thereby improving processability. The insulating pattern SP includes a first portion SP1 in a pillar shape made from a negative photoresist material NPR and a second portion SP2 in a dome shape made from a positive photoresist material PPR. This configuration enhances bonding reliability because the first portion SP1 has a higher modulus (e.g., elastic modulus) than the second portion SP2, allowing it to better support pressure and maintain restoring force. When pressure is applied during bonding, the second portion SP2 allows resin discharge and concentrates pressure, facilitating the tearing of a thin film in the second conductive pattern CL2 and improving contact between the second layer and the bump BP1.

Additionally, for example, a display panel of the present disclosure may include an insulating pattern with materials having different moduli (e.g., elastic moduli), further enhancing bonding reliability. The combination of a pillar and dome shape in the insulating pattern improves the overall bonding reliability of the display panel, ensuring better initial resistance and reliability resistance.

Furthermore, for example, a manufacturing method described in the present disclosure does not require additional processes to provide curvature to the upper surface of the insulating pattern, which simplifies the manufacturing process and improves processability. This method allows for the efficient production of high-resolution display panels with enhanced bonding reliability and reduced risk of short circuits or energization failures.

As used herein, the terms “use,” “using,” and “used” may be considered synonymous with the terms “utilize,” “utilizing,” and “utilized,” respectively. As used herein, expressions such as “at least one of”, “one of”, and “selected from”, when preceding a list of elements, modify the entire list of elements and do not modify the individual elements of the list. For example, “at least one selected from among a, b and c”, “at least one of a, b or c”, and “at least one of a, b and/or c” may indicate only a, only b, only c, both (e.g., simultaneously) a and b, both (e.g., simultaneously) a and c, both (e.g., simultaneously) b and c, all of a, b, and c, or variations thereof.

The use of “may” when describing embodiments of the inventive concept refers to “one or more embodiments of the inventive concept.”

As used herein, the term “about,” and similar terms are used as terms of approximation and not as terms of degree, and are intended to account for the inherent deviations in measured or calculated values that would be recognized by those of ordinary skill in the art. “About” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Also, any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

Here, unless otherwise defined, the listing of steps, tasks, or acts in a particular order should not necessarily means that the invention or claims require that particular order. That is, the general rule that unless the steps, tasks, or acts of a method (e.g., a method claim) actually recite an order, the steps, tasks, or acts should not be construed to require one.

A person of ordinary skill in the art, in view of the present disclosure in its entirety, would appreciate that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

The display device, the electronic device, a device for manufacturing the same and/or any other relevant devices or components according to embodiments of the present invention described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the present disclosure.

Although description has been made with reference to one or more embodiments of the present disclosure, it is understood that the present disclosure should not be limited to these embodiments, but one or more suitable changes and modifications may be made by one ordinary skilled in the art within the spirit and scope of the present disclosure as hereinafter claimed. Therefore, the technical scope of the present disclosure is not limited to the contents described in the detailed description of the specification, but should be determined by the accompanying claims, and equivalents thereof.

What is claimed is:

1. A display panel comprising:
a pixel,
a signal line electrically connected to the pixel, and
a signal pad connected to the signal line,
wherein the signal pad comprises:
a first conductive pattern connected to one side portion of the signal line,
a second conductive pattern on the first conductive pattern, and
an insulating pattern comprising a first portion on the first conductive pattern and a second portion on the first portion,
wherein the first portion has a pillar shape, and
wherein the second portion has a dome shape.

2. The display panel of claim 1, wherein in a plan view, the insulating pattern is on an inner side of each of the first conductive pattern and the second conductive pattern.

3. The display panel of claim 1, wherein
the insulating pattern is directly on the first conductive pattern, and
the second conductive pattern covers the insulating pattern and a portion of the first conductive pattern not covered by the insulating pattern.

4. The display panel of claim 1, wherein
the first portion comprises an upper surface in contact with the second portion,
the second portion comprises a lower surface in contact with the first portion, and
the upper surface of the first portion is congruent to the lower surface of the second portion.

5. The display panel of claim 1, wherein
the first portion has a quadrangular shape in a cross-sectional view, and
the second portion comprises an upper surface in contact with the second conductive pattern, and the upper surface of the second portion has an upwardly convex shape.

6. The display panel of claim 1, wherein an elastic modulus of the first portion is greater than an elastic modulus of the second portion.

7. The display panel of claim 1, wherein
the first portion comprises a material formed from a negative photoresist material, and
the second portion comprises a material formed from a positive photoresist material.

8. The display panel of claim 1, wherein the first portion has a multi-layered structure.

9. The display panel of claim 1, wherein each of the first portion and the second portion independently comprises a polymer.

10. An electronic device comprising:
a display module;
a window on the display module; and
an accommodation member accommodating the display module,
wherein the display module comprises:
a pixel,
a signal line electrically connected to the pixel, and
a signal pad connected to the signal line,
wherein the signal pad comprises:
a first conductive pattern connected to one side portion of the signal line,
a second conductive pattern on the first conductive pattern, and
an insulating pattern comprising a first portion on the first conductive pattern and a second portion on the first portion, and
wherein an elastic modulus of the first portion is greater than an elastic modulus of the second portion.

11. The electronic device of claim 10, wherein in a plan view, the insulating pattern is on an inner side of each of the first conductive pattern and the second conductive pattern.

12. The electronic device of claim 10, wherein
the insulating pattern is directly on the first conductive pattern, and
the second conductive pattern covers the insulating pattern and a portion of the first conductive pattern on which the insulating pattern is not arranged.

13. The electronic device of claim 10, wherein
the first portion comprises an upper surface in contact with the second portion,
the second portion comprises a lower surface in contact with the first portion, and
the upper surface of the first portion is congruent to the lower surface of the second portion.

14. The electronic device of claim 10, wherein
the first portion has a pillar shape, and
the second portion has a dome shape.

15. The electronic device of claim 10, wherein
the first portion has a quadrangular shape in a cross-sectional view, and
the second portion comprises an upper surface in contact with the second conductive pattern, and the upper surface of the second portion has an upwardly convex shape.

16. The electronic device of claim 10, wherein
the first portion is formed from a negative photoresist material, and
the second portion is formed from a positive photoresist material.

17. The electronic device of claim 10, wherein the first portion has a multi-layered structure.

18. The electronic device of claim 10, wherein each of the first portion and the second portion independently comprises a polymer.

19. A method comprising:
providing a preliminary signal pad comprising a first conductive pattern connected to one side portion of a signal line; and
forming, on the preliminary signal pad, an insulating pattern comprising a first portion and a second portion,
wherein the forming of the insulating pattern comprises:
forming the first portion on the preliminary signal pad in a first region by utilizing a negative photoresist material, and
forming the second portion on the first portion by utilizing a positive photoresist material,
wherein the method is a method of manufacturing a display panel.

20. The method of claim 19, wherein
the forming of the first portion comprises:
applying the negative photoresist material onto the preliminary signal pad;
exposing the negative photoresist material in the first region; and
forming the first portion in the first region by developing and curing the negative photoresist material, and
the forming of the second portion comprises:
applying the positive photoresist material onto the preliminary signal pad and the first portion,
exposing a second region, around the first region in a plan view, of the positive photoresist material, and
forming the second portion on the first portion by developing and curing the positive photoresist material.
